(19) United States
(12) Patent Application Publication
(10) Pub. No.: US 2025/0087489 A1
(43) Pub. Date: Mar. 13, 2025

(54) CHIP MANUFACTURING METHOD

(71) Applicant: DISCO CORPORATION, Tokyo (JP)

(72) Inventor: Taro ARAKAWA, Tokyo (JP)

(21) Appl. No.: 18/820,909

(22) Filed: Aug. 30, 2024

(30) Foreign Application Priority Data
Sep. 11, 2023 (JP) 2023-146919

(51) Int. Cl. H01L 21/268; H01L 21/78

(52) U.S. Cl. CPC H01L 21/268; H01L 21/78

(57) ABSTRACT

A chip manufacturing method for manufacturing a chip includes: forming shield tunnels each having a fine pore and an amorphous region surrounding the fine pore along the planned division line, by relatively moving the wafer and a focal point of a laser beam having a wavelength transmissive to the wafer in a condition in which the focal point is positioned inside the wafer; and dividing the wafer along the planned division line where the shield tunnels are formed by applying an external force to the wafer. Forming the shield tunnels includes: shaping the laser beam into a shape having a longitudinal direction and a transverse direction; and irradiating the wafer with the laser beam along the planned division line in a state where the longitudinal direction is set to intersect an extending direction of the planned division line.

### CROSS-REFERENCE TO RELATED APPLICATION(S)

The present application claims priority to and incorporates by reference the entire contents of Japanese Patent Application No. 2023-146919 filed in Japan on Sep. 11, 2023.

### BACKGROUND

The present disclosure relates to a chip manufacturing method.

In order to divide a semiconductor wafer into chips, there has been known a method of: irradiating the wafer with a laser beam having a wavelength transmissive to the wafer along a planned division line in a condition in which a focal point of the laser beam is positioned inside the wafer, so as to form a modified layer; and dividing the wafer with the modified layer as a starting point (see JP 3408805 B2). This method has a problem of poor productivity because, when a thick wafer is divided into individual devices, it is necessary to form multi-stage modified layers stacked in the thickness direction.

Therefore, there has been proposed a method of forming shield tunnels each including a fine pore and an amorphous region surrounding the fine pore by irradiating a wafer along planned division lines with a laser beam having a wavelength transmissive to the wafer in a condition in which a focal point of the laser beam is positioned inside the wafer (see JP 6062287 B2). This method makes it possible to reduce the number of times a thick wafer is irradiated with a laser beam as compared to that in the conventional method, resulting in extremely improved productivity.

However, in the method according to JP 6062287 B2, a high dividing force is required at the time of division, and a high load is applied at the time of division, thereby increasing the load applied to the wafer. Therefore, there is a possibility that processing defects such as chippings and cracks occur.

### SUMMARY

A chip manufacturing method according to one aspect of the present disclosure is for manufacturing a chip having a predetermined shape by irradiating a wafer with a laser beam along a planned division line set on a front surface of the wafer. The chip manufacturing method includes: forming shield tunnels each having a fine pore and an amorphous region surrounding the fine pore along the planned division line, by relatively moving the wafer and a focal point of a laser beam having a wavelength transmissive to the wafer in a condition in which the focal point is positioned inside the wafer; and dividing the wafer along the planned division line where the shield tunnels are formed by applying an external force to the wafer. Forming the shield tunnels includes: shaping the laser beam into a shape having a longitudinal direction and a transverse direction; and irradiating the wafer with the laser beam along the planned division line in a state where the longitudinal direction is set to intersect an extending direction of the planned division line.

### BRIEF DESCRIPTION OF THE DRAWINGS

FIG. 1 is a perspective view illustrating an example of a wafer to be processed by a chip manufacturing method according to an embodiment;

FIG. 2 is a flowchart illustrating a flow of the chip manufacturing method according to the embodiment;

FIG. 3 is a perspective view illustrating a configuration example of a laser processing device that performs a shield tunnel forming step illustrated in FIG. 2;

FIG. 4 is a schematic configuration diagram of a laser beam irradiation unit of the laser processing device illustrated in FIG. 3;

FIG. 5 is a partial cross-sectional side view illustrating a state in the shield tunnel forming step illustrated in FIG. 2;

FIG. 6 is a partial cross-sectional side view illustrating a state after the state of FIG. 5;

FIG. 7 is a perspective view schematically illustrating a structure of a shield tunnel;

FIG. 8 is a perspective view illustrating an example of a shape of the laser beam after being shaped;

FIG. 9 is a partial cross-sectional side view illustrating a state in a wafer dividing step illustrated in FIG. 2;

FIG. 10 is a partial cross-sectional side view illustrating a state after the state of FIG. 9;

FIG. 11 is a perspective view illustrating a shape of a laser beam in a comparative example; and

FIG. 12 is a perspective view illustrating an example of a wafer to be processed by a chip manufacturing method according to a modification.

### DETAILED DESCRIPTION

Embodiments according to the present disclosure will be described in detail with reference to the drawings. The present invention is not limited by the contents described in the following embodiments. In addition, the constituent elements described below include those that can be easily conceived by those skilled in the art and those that are substantially the same. Furthermore, the configurations described below can be appropriately combined. In addition, various omissions, substitutions, or changes of the configuration can be made without departing from the gist of the present invention.

### Embodiment

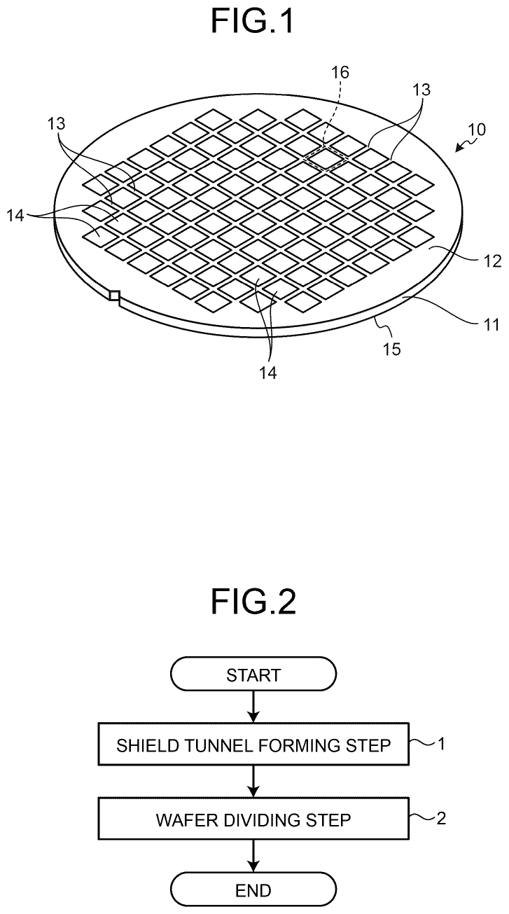

A method for manufacturing a chip 16 according to an embodiment of the present invention will be described with reference to the drawings. FIG. 1 is a perspective view illustrating an example of a wafer 10 to be processed by a method for manufacturing a chip 16 according to an embodiment. The wafer 10 illustrated in FIG. 1 is a disk-shaped wafer, such as a semiconductor device wafer or an optical device wafer, having a substrate 11 made of silicon (Si), sapphire (Al₂O₃), gallium arsenide (GaAs), silicon carbide (SiC), lithium tantalate (LiTaO₃), or the like.

The wafer 10 has, on a front surface 12 thereof, a plurality of planned division lines 13 set in a lattice shape and devices 14 formed in regions sectioned by the planned division lines 13 that intersect one another. The device 14 is, for example, an integrated circuit such as an integrated circuit (IC) or a large scale integration (LSI), or an image sensor such as a charge coupled device (CCD) or a complementary metal oxide semiconductor (CMOS).

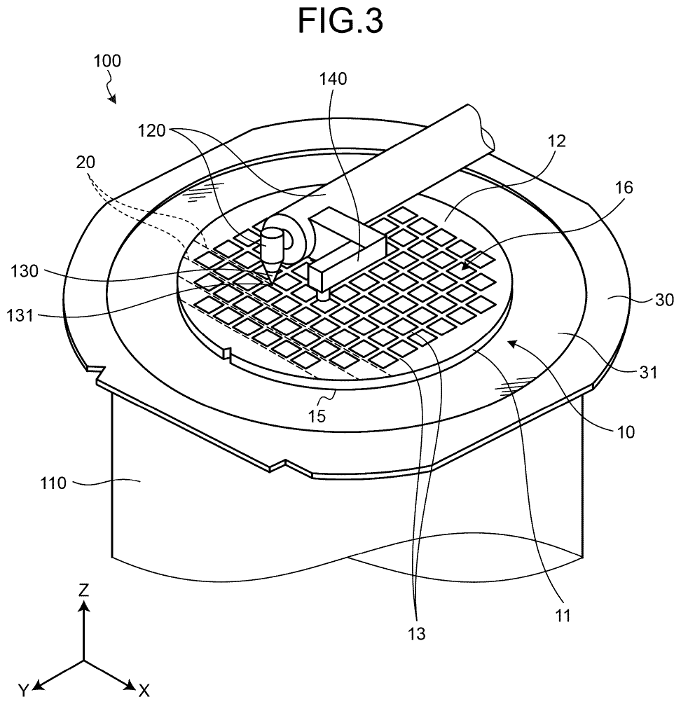

The wafer 10 is conveyed and processed while being supported by, for example, an annular frame 30 and a tape 31 illustrated in FIG. 3, etc. to be described below. The frame 30 is an annular plate member made of a metal or a resin and having an opening larger than an outer diameter of the wafer 10. The tape 31 in the form of a sheet having an outer diameter larger than the opening of the frame 30, and is bonded to a back surface of the frame 30 so as to cover the opening of the frame 30.

The tape 31 may include, for example, a substrate layer made of an expandable synthetic resin and an adhesive layer stacked on the substrate layer, and made of an expandable and adhesive synthetic resin. Alternatively, the tape 31 may be made of a thermoplastic resin without having an adhesive layer. The wafer 10 is positioned at a predetermined position in the opening of the frame 30, and is fixed to the frame 30 and the tape 31 by bonding a front surface 12 or a back surface 15 (the back surface 15 in the embodiment) to the tape 31.

The wafer 10 is divided into individual devices 14 along the plurality of planned division lines 13 to manufacture chips 16. The chip 16 has a square shape in the embodiment, but may have a rectangular shape. The wafer 10 has a disk shape in the embodiment, but may not have a disk shape in the present invention.

FIG. 2 is a flowchart illustrating a flow of the method for manufacturing the chip 16 according to the embodiment. The method for manufacturing the chip 16 is a method for manufacturing a plurality of chips 16 from the wafer 10 to be processed. As illustrated in FIG. 2, the method for manufacturing the chip 16 includes a shield tunnel forming step 1 and a wafer dividing step 2.

### Laser Processing Device 100

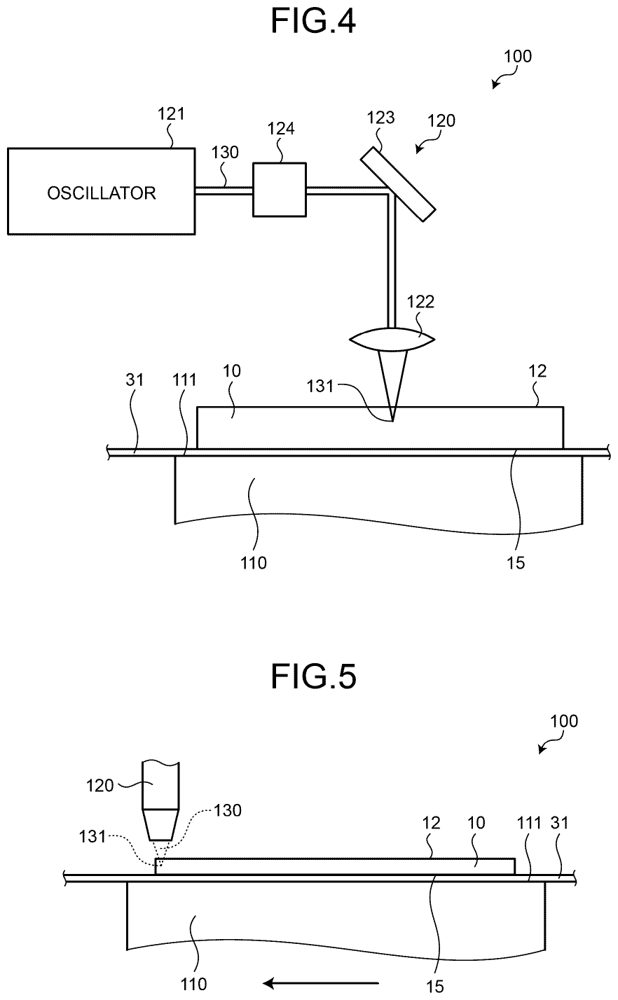

First, a configuration example of a laser processing device 100 that performs the shield tunnel forming step 1 will be described. FIG. 3 is a perspective view illustrating a configuration example of the laser processing device 100 that performs the shield tunnel forming step 1 illustrated in FIG. 2. FIG. 4 is a schematic configuration diagram of a laser beam irradiation unit 120 of the laser processing device 100 illustrated in FIG. 3.

The laser processing device 100 includes a chuck table 110, a laser beam irradiation unit 120, an imaging unit 140, and a moving unit (not illustrated) that relatively moves the chuck table 110 and the laser beam irradiation unit 120. In the following description, the X-axis direction is one direction on a horizontal plane, and is a feeding direction. The Y-axis direction is a direction orthogonal to the X-axis on the horizontal plane, and is an indexing-forward direction. The Z-axis direction is a direction orthogonal to the X-axis direction and the Y-axis direction, and is a focal position adjustment direction.

The chuck table 110 is a support table that holds the wafer 10 on a holding surface 111. For example, the chuck table 110 holds the back surface 15 of the wafer 10 via the tape 31, so that the front surface 12 is exposed. The holding surface 111 has a disk shape and formed of porous ceramic or the like, and is a flat surface parallel to the horizontal direction in the embodiment. The holding surface 111 is connected to a vacuum suction source, for example, via a vacuum suction path, and holds the wafer 10 placed on the holding surface 111 in a sucked manner.

The laser beam irradiation unit 120 is a unit that irradiates the wafer 10 held on the chuck table 110 with a pulsed laser beam 130. As illustrated in FIG. 4, the laser beam irradiation unit 120 includes an oscillator 121, a condenser 122, a mirror 123, and a beam shaping unit 124.

The oscillator 121 oscillates the laser beam 130 having a predetermined wavelength for processing the wafer 10. The condenser 122 is a condensing lens, which condenses the laser beam 130 emitted from the oscillator 121, and emits the laser beam 130 toward the wafer 10 held on the holding surface 111 of the chuck table 110. The mirror 123 is provided on an optical path of the laser beam 130 between the oscillator 121 and the condenser 122 to reflect the laser beam 130 emitted from the oscillator 121 to be guided to the condenser 122.

The beam shaping unit 124 is provided on the optical path of the laser beam 130 between the oscillator 121 and the condenser 122 to shape the beam shape of the laser beam 130 emitted from the oscillator 121 into a predetermined shape. The beam shaping unit 124 includes, for example, a well-known slit mask, a diffractive optical element (DOE), or a spatial light modulator (a liquid crystal on silicon (LCOS)). The slit mask has a plate-shaped base capable of blocking the laser beam 130 and a hole formed in the base. The diffractive optical element adjusts the shape of the laser beam 130 using a light diffraction phenomenon. The spatial light modulator includes a display unit that displays a phase pattern for adjusting optical characteristics when transmitting or reflecting (transmitting in the arrangement illustrated in FIG. 4) the incident laser beam 130, so as to adjust the shape of the emitted laser beam 130.

The imaging unit 140 illustrated in FIG. 3 images the wafer 10 held on the chuck table 110. The imaging unit 140 includes a CCD camera or an infrared camera. For example, the imaging unit 140 is fixed to be adjacent to the condenser 122 (see FIG. 4) of the laser beam irradiation unit 120. The imaging unit 140 images the wafer 10 to obtain an image used for performing an alignment of the wafer 10 and the laser beam irradiation unit 120, and outputs the obtained image.

### Shield Tunnel Forming Step 1

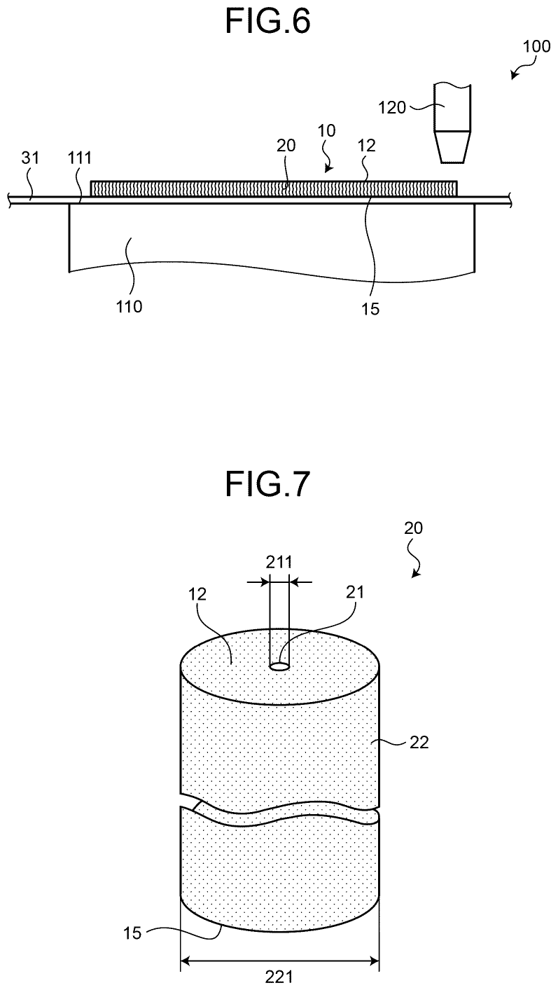

FIG. 5 is a partial cross-sectional side view illustrating a state in the shield tunnel forming step 1 illustrated in FIG. 2. FIG. 6 is a partial cross-sectional side view illustrating a state after the state of FIG. 5 FIG. 7 is a perspective view schematically illustrating a structure of a shield tunnel 20. The shield tunnel forming step 1 is a step of forming shield tunnels 20 each having a fine pore 21 and an amorphous region 22 surrounding the fine pore 21 along the planned division lines 13, by relatively moving the wafer 10 and a focal point 131 of the laser beam 130 having a wavelength transmissive to the wafer 10 in a condition in which the focal point 131 is positioned inside the wafer 10.

In the shield tunnel forming step 1, first, the back surface 15 of the wafer 10 is held in a sucked manner on the holding surface 111 of the chuck table 110 via the tape 31. Next, the condenser 122 (see FIG. 4) of the laser beam irradiation unit 120 is aligned with the planned division line 13 of the wafer 10. Specifically, the moving unit (not illustrated) moves the chuck table 110 to a processing region below the laser beam irradiation unit 120.

Next, the imaging unit 140 (see FIG. 3) images the wafer 10, so that the planned division line 13 is detected. When the planned division line 13 is detected, an alignment is performed to align an irradiation unit of the laser beam irradiation unit 120 with the planned division line 13 of the wafer 10. After the irradiation unit of the laser beam irradiation unit 120 is aligned to face the planned division line 13 in the vertical direction, a focal point 131 of the laser beam 130 is set inside the wafer 10.

In the shield tunnel forming step 1, next, the pulsed laser beam 130 is emitted into the wafer 10, while the chuck table 110 and the laser beam irradiation unit 120 are relatively moved in the feeding direction so that the laser beam 130 is emitted along the planned division line 13. As a result, the focal point 131 and the wafer 10 relatively move, the shield tunnels 20 each extending from the vicinity of the focal point 131 of the laser beam 130 positioned inside the wafer 10 toward the front surface 12 and the back surface 15 of the wafer 10 are formed along the planned division line 13 as illustrated in FIG. 6. The shield tunnels 20 are formed at predetermined intervals along the planned division line 13 owing to the irradiation of the pulsed laser beam 130.

As illustrated in FIG. 7, the shield tunnel 20 has the fine pore 21 extending from the front surface 12 to the back surface 15 of the wafer 10, and a cylindrical amorphous region 22 surrounding the fine pore 21. The fine pore 21 has an inner diameter 211 of about 1 μm, the amorphous region 22 has an outer diameter 221 of about 5 μm, and an interval between the adjacent amorphous regions 22 is about 10 μm.

FIG. 8 is a perspective view illustrating an example of a shape of the laser beam 130 after being shaped. In FIG. 8, the wafer 10 is not entirely illustrated, and only the planned division line 13 on the back surface 15 is illustrated. In FIG. 8, it is assumed that the focal point 131 is positioned inside the wafer 10. That is, although only a portion of the shield tunnel 20 formed below the focal point 131 is illustrated in FIG. 8, the shield tunnel 20 is actually formed also above the focal point 131.

In the shield tunnel forming step 1, the beam shaping unit 124 shapes the laser beam 130 into a shape having a longitudinal direction 132 and a transverse direction 133 in. In the example illustrated in FIG. 8, the beam shaping unit 124 shapes the laser beam 130 into an oval shape. The laser beam 130 may be shaped into, for example, a rectangular shape or an elliptical shape. The “rectangular shape” mentioned herein is not limited to a strict rectangular shape, and may be a shape with rounded corners or an oval shape as illustrated in FIG. 8. In addition, the “elliptical shape” mentioned herein is not limited to a strict elliptical shape, and may be any shape as long as it is a shape defined by a closed curve as a whole.

When the shaped laser beam 130 is emitted to the wafer 10 while being condensed by the condenser 122, the longitudinal direction 132 is set to intersect an extending direction of the planned division line 13. In the shield tunnel forming step 1 according to the embodiment, the longitudinal direction 132 is set to be orthogonal to the extending direction of the planned division line 13.

The processing conditions in the embodiment are as follows. The defocus is a device setting distance from the front surface 12 of the wafer 10 to the focal point 131. In the embodiment, the beam diameter before focus is a diameter of the laser beam 130 before entering the beam shaping unit 124 after being emitted from the oscillator 121. The beam shape after focus is a shape of the spot of the laser beam 130 on the front surface 12.
Wavelength: 1064 nm
Output: 1.0 W
Defocus: 0.010 mm
Frequency: 40 kHz
Feed speed: 700 mm/s
Beam diameter before focus: 3.0 mm
Beam shape after focus: oval shape of 60 μm×20 μm

### Wafer Dividing Step 2

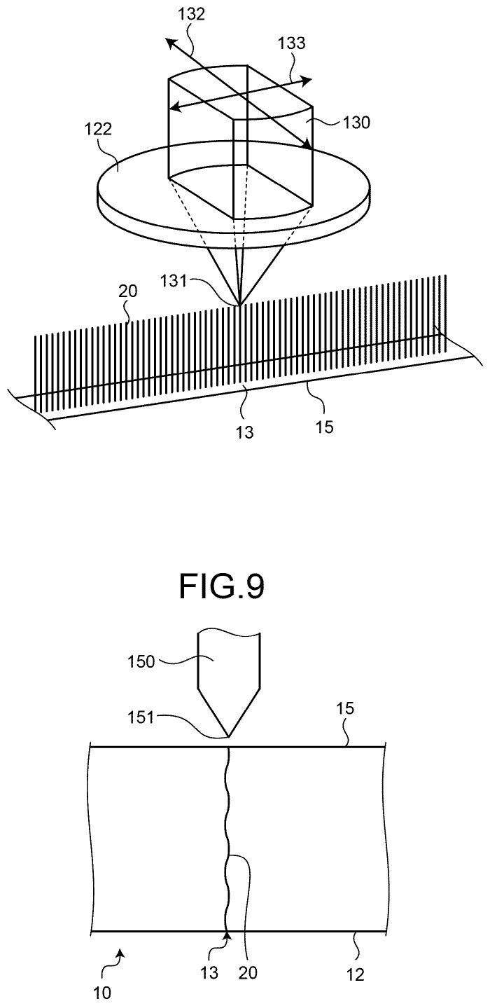

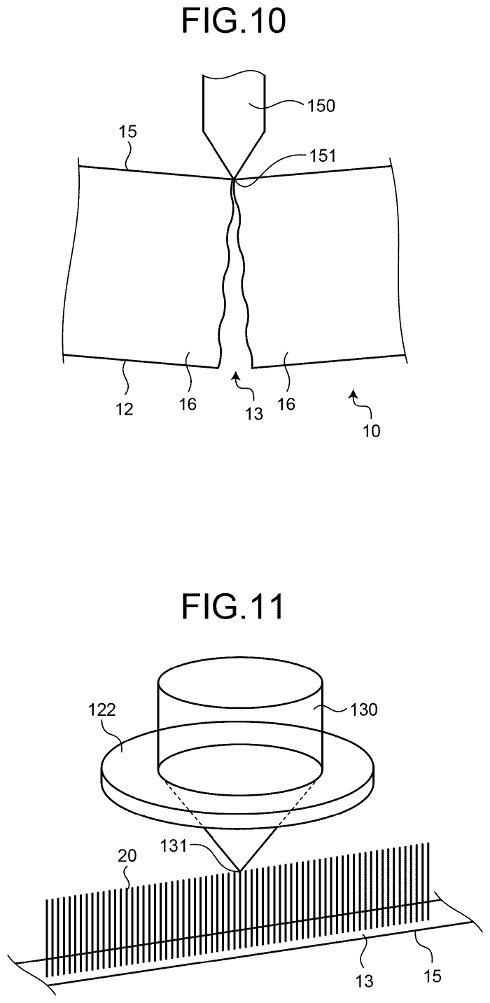

FIG. 9 is a partial cross-sectional side view illustrating a state in the wafer dividing step 2 illustrated in FIG. 2. FIG. 10 is a partial cross-sectional side view illustrating a state after the state of FIG. 9. The wafer dividing step 2 is a step of dividing the wafer 10 along the planned division line 13 where the shield tunnels 20 are formed by applying an external force to the wafer 10.

As illustrated in FIGS. 9 and 10, in the wafer dividing step 2 according to the embodiment, a breaking blade 150 divides the wafer 10 by applying a pressing force in a state where a blade-shaped tip 151 is brought into contact with the wafer 10 along the planned division line 13 where the shield tunnels 20 are formed from the back surface 15 of the wafer 10. The breaking blade 150 is mounted on a known breaking device, and can move up and down in the vertical direction with respect to the held wafer 10. The breaking blade 150 is formed to extend in one horizontal direction (a direction perpendicular to the paper surface in FIGS. 9 and 10).

In the wafer dividing step 2, first, the wafer 10 is held by a holding mechanism such as a holding table of the braking device. Next, the tip 151 of the breaking blade 150 is aligned with the planned division line 13 where the shield tunnels 20 are formed. Next, the breaking blade 150 is brought close to the holding table, and the tip 151 is brought into contact with the back surface 15 of the planned division line 13.

Further, by pressing the breaking blade 150 toward the front surface 12 of the wafer 10, a bending stress is applied to the wafer 10 together with the holding mechanism that holds the wafer 10, and the wafer 10 is divided along the planned division line 13 with the shield tunnels 20 formed along the planned division line 13 as fracture starting points. Similarly, for all of the planned division lines 13 of the wafer 10, the alignment of the tip 151 of the breaking blade 150 and the application of the bending stress by pressure at the tip 151 are sequentially performed to divide the wafer 10 along all of the planned division lines 13 of the wafer 10 and individualize the wafer 10 into chips 16.

### Comparative Example

FIG. 11 is a perspective view illustrating a shape of a laser beam 130 in a comparative example. In FIG. 11, the wafer 10 is not entirely illustrated, and only the planned division line 13 on the back surface 15 is illustrated. In FIG. 11, it is assumed that the focal point 131 is positioned inside the wafer 10. That is, although only a portion of the shield tunnel 20 formed below the focal point 131 is illustrated in FIG. 11, the shield tunnel 20 is actually formed also above the focal point 131.

In the comparative example illustrated in FIG. 11, the laser beam 130 is condensed by the condenser 122 and emitted to the wafer 10, not shaped by the beam shaping unit 124, with the beam shape kept in a perfect circular shape. The processing conditions in the comparative example are as follows.
Wavelength: 1064 nm
Output: 1.0 W
Defocus: 0.010 mm
Frequency: 40 kHz
Feed speed: 700 mm/s
Beam diameter before focus: 3.0 mm
Beam shape after focus: perfect circle with ϕ60 μm

Table 1 shows a breaking strength (N) in the wafer dividing step 2 of each of the embodiment and the comparative example. The breaking strength is a maximum value of a pressing force measured immediately before the wafer 10 is divided when the wafer 10 is pressed by the tip 151 of the breaking blade 150.

TABLE 1

| | Embodiment | Comparative example |
|---|---|---|
| Minimum value | 57.2 | 88.6 |
| Average value | 110.3 | 118.3 |
| Maximum value | 148.7 | 156.4 |

As shown in Table 1, all of a minimum value, an average value, and a maximum value for the breaking strength in the embodiment is lower than those for the breaking strength in the comparative example. That is, it was found that the shaping of the laser beam 130 into the oval shape decreased the breaking strength and improved the divisibility.

Here, a portion of the laser beam 130 condensed by the condenser 122 and passing the center of the condenser 122, is emitted into the wafer closer to the front surface 12 of the wafer 10, while a portion of the laser beam 130 passing the vicinity of the outer periphery of the condenser 122 is emitted into the wafer closer to the back surface 15 of the wafer 10. Therefore, when the total energy amount of the laser beam 130 of the embodiment illustrated in FIG. 8 is the same as the total energy amount of the laser beam 130 of the comparative example illustrated in FIG. 11, with respect to the laser beam 130 of the embodiment, a ratio of the laser beam 130 passing the outer edge portion of the condenser 122 decreases, and the intensity of the laser beam 130 emitted into the wafer closer to the front surface 12 of the wafer 10 is higher than the intensity of the laser beam 130 emitted into the wafer closer to the back surface 15. Therefore, it can be considered that the crack propagates more easily on the front surface 12, thereby improving the divisibility.

### Modification

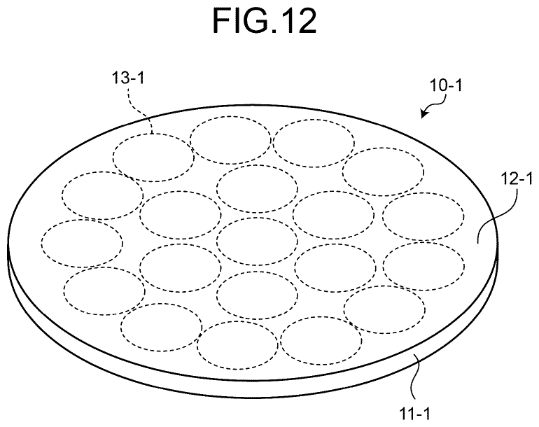

FIG. 12 is a perspective view illustrating an example of a wafer 10-1 to be processed by a method for manufacturing a chip 16 according to a modification. Similarly to the wafer 10 according to the embodiment, the wafer 10-1 illustrated in FIG. 12 is a disk-shaped wafer, such as a semiconductor device wafer or an optical device wafer, having a substrate 11-1 made of silicon, sapphire, gallium arsenide, silicon carbide, lithium tantalate, or the like.

The wafer 10-1 according to the modification is different from the wafer 10 according to the embodiment in that planned division lines 13-1 are set in a shape including a plurality of circles, not in a lattice shape. The method for manufacturing the chip 16 according to the present invention can be applied even to the wafer 10-1. For example, in the shield tunnel forming step 1, the laser beam 130 is emitted from a front surface 12-1 side in a condition in which the focal point 131 of the laser beam 130 is positioned inside the wafer 10-1, similarly to the embodiment. In the modification, by operating the chuck table 110 using a well-known planar motor or scanning the laser beam 130 by a well-known laser scanning unit, the focal point 131 is moved along the planned division line 13-1 having a small circular shape to form shield tunnels 20 along the planned division line 13-1. At this time, the laser beam 130 is shaped to have a major axis or a longitudinal direction 132 in a traveling direction of the focal point 131.

As described above, in the method for manufacturing the chip 16 according to each of the embodiment and the modification, the laser beam 130 is shaped into a shape having a longitudinal direction 132 and a transverse direction 133, such as a rectangular shape or an elliptical shape, and is emitted so that the longitudinal direction 132 intersects the extending direction of the planned division line 13. As a result, as compared with a case where a laser beam 130 having a perfect circular shape is emitted, the upper portion of the wafer 10 where the inner side of the laser beam is condensed has a higher processing intensity, that is, the wafer 10 is easy to crack and break. This makes it possible to decrease the breaking strength and reduce the load applied for division, so that processing defects such as chippings and cracks can be suppressed.

According to the present disclosure, it is possible to suppress a processing defect by reducing a load applied at the time of division while maintaining the productivity of the wafer.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A chip manufacturing method for manufacturing a chip having a predetermined shape by irradiating a wafer with a laser beam along a planned division line set on a front surface of the wafer, the chip manufacturing method comprising:
forming shield tunnels each having a fine pore and an amorphous region surrounding the fine pore along the planned division line, by relatively moving the wafer and a focal point of a laser beam having a wavelength transmissive to the wafer in a condition in which the focal point is positioned inside the wafer; and
dividing the wafer along the planned division line where the shield tunnels are formed by applying an external force to the wafer, wherein
forming the shield tunnels includes
shaping the laser beam into a shape having a longitudinal direction and a transverse direction, and
irradiating the wafer with the laser beam along the planned division line in a state where the longitudinal direction is set to intersect an extending direction of the planned division line.

2. The chip manufacturing method according to claim 1, wherein
forming the shield tunnels includes irradiating the wafer with the laser beam along the planned division line in a state where the longitudinal direction is set to be orthogonal to the extending direction of the planned division line.

3. The chip manufacturing method according to claim 1, wherein
forming the shield tunnels includes shaping the laser beam into a rectangular shape.

4. The chip manufacturing method according to claim 1, wherein
forming the shield tunnels includes shaping the laser beam into an elliptical shape.
